(19) United States
(12) Patent Application Publication
(10) Pub. No.: US 2008/0190660 A1
(43) Pub. Date: Aug. 14, 2008

(54) Magnetic Induction Protecting Structure

(76) Inventors: Ming-Chih HUANG, Taichung (TW); Chih-Mao Shiao, Taichung (TW)

Correspondence Address: Dr. BANGER SHIA, 102 Lindencrest Ct., Sugar Land, TX, 77479-5201, US

(21) Appl. No.: 11/672,913

(22) Filed: Feb. 8, 2007

(51) Int. Cl. H05K 9/00

(52) U.S. Cl. 174/377; 307/91

(57) ABSTRACT

A magnetic induction protecting structure comprises a platform, an induction ruler, an induction head and a protection assembly. The protection assembly covers an induction distance between the induction head and the induction ruler completely for scraping off the chips and dust on the induction ruler and to prevent the chips and dust from being fallen into or accumulated in the induction distance, so as to ensure the quality of the magnetic induction signals between the induction head and the induction ruler, and to prolong the life of the induction head and the induction ruler.

### BACKGROUND OF THE INVENTION

1. Field of the Invention

The present invention relates to a protecting structure, and more particularly to a magnetic induction protecting structure.

2. Description of the Prior Art

Conventional induction head and induction ruler are usually disposed on a table of a processing machine, the induction head is magnetically moveable relative to the induction ruler, and between the induction head and the induction ruler is formed an induction distance with no protecting structure. When processing, the processing machine is likely to cause chips or dust which will fall into and accumulate in the induction distance, as a result, the induction head and the induction ruler will be scraped and the induction signals will be influenced, and the operation will be disturbed or even halted. In order to improve this problem, a magnetic induction protecting structure is developed.

Referring to FIG. 1, the magnetic induction protecting structure comprises a platform P10, an induction ruler P20, an induction head P30 and a protection assembly P40.

The platform P10 is rectangular.

The induction ruler P20 is rectangular sheet-shaped and is positioned to a top surface of the platform P10.

The induction head P30 is rectangular, at an end of a bottom of the induction head P30 is formed an induction portion P31 magnetically moveable relative to the induction ruler P20, and an induction distance A is formed between the induction portion P31 and the induction ruler P20.

The protection assembly P40 has a front scraping piece P41 and a rear scraping piece P42, the front scraping piece P41 is formed with a positioning portion P411 and a scraping portion P412, and the rear scraping piece P42 is formed with a positioning portion P421 and a scraping portion P422. The positioning portions P411 and P421 of the front and rear scraping pieces P41 and P42 are locked to both end surfaces of the induction portion P31 of the induction head P30 by screws respectively, enabling the scraping portions P412 and P422 of the front and rear scraping pieces P41 and P42 to abut against the surface of the induction ruler P20 respectively. However, the conventional magnetic induction protecting structure has the following disadvantages:

When the induction head P30 is magnetically moveable relative to the induction ruler P20, the front and rear scraping pieces P41 and P42 of the protection assembly P40 are provided for scraping off the chips or dust accumulated on the induction ruler P20, but since there is no anti-dust protection device between the sides of the induction head P30 and the induction ruler P20, the chips or dust will likely to fall into or accumulate in the induction distance A. Thereby, how to eliminate the chips or dust between the induction head P30 and the induction ruler P20 has become an important issue for the manufacturers.

The present invention has arisen to mitigate and/or obviate the afore-described disadvantages.

### SUMMARY OF THE INVENTION

The primary objective of the present invention is to provide a magnetic induction protecting structure comprises a protection assembly for covering an induction distance between an induction head and an induction ruler completely.

To achieve the object of the present invention, a magnetic induction protecting structure comprises a platform, an induction ruler, an induction head and a protection assembly. An anti-dust portion formed at one side of the protection assembly has two opposite scraping portions and two opposite insulating portions, and the protection assembly is provided for covering an induction distance between the induction head and the induction ruler completely, so as to scrape the chips or dust off the induction ruler and to prevent the chips or dust from being fallen into or accumulated in the induction distance, thus ensuring the quality of the magnetic induction signals between the induction head and the induction ruler.

The further objective of the present invention is to provide a magnetic induction protecting structure which is easy to assemble or disassemble, wherein a first jointing portion of an induction head and a second jointing portion of a protection assembly can be positioned directly.

To achieve the object of the present invention, a magnetic induction protecting structure comprises a platform, an induction ruler, an induction head and a protection assembly. One side of the induction head is formed with a first jointing portion, and one side of the protection assembly is formed with a second jointing portion to be positioned correspondingly to the first jointing portion without cooperating with any other components.

The present invention will become more obvious from the following description when taken in connection with the accompanying drawings, which show, for purpose of illustrations only, the preferred embodiments in accordance with the present invention.

### BRIEF DESCRIPTION OF THE DRAWINGS

FIG. 1 is a perspective view of a conventional magnetic induction protecting structure in accordance with the present invention;

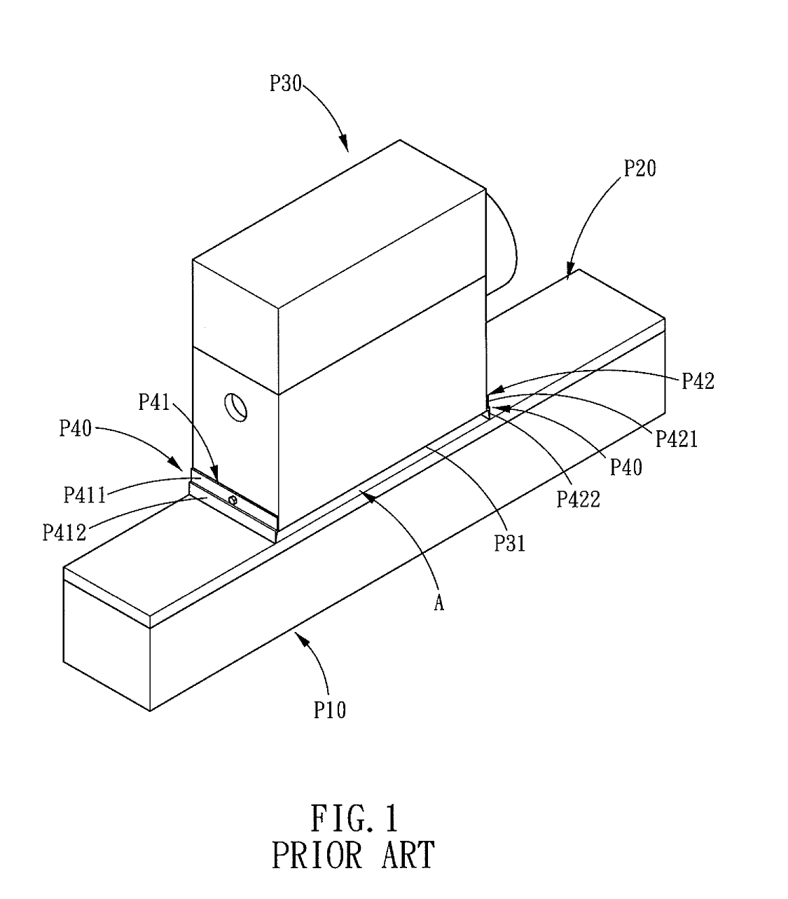

FIG. 2 is a perspective view of a magnetic induction protecting structure in accordance with the present invention;

FIG. 3 is a cross sectional view of the magnetic induction protecting structure in accordance with the present invention; and

FIG. 4 is another cross sectional view of the magnetic induction protecting structure in accordance with the present invention.

### DETAILED DESCRIPTION OF THE PREFERRED EMBODIMENTS

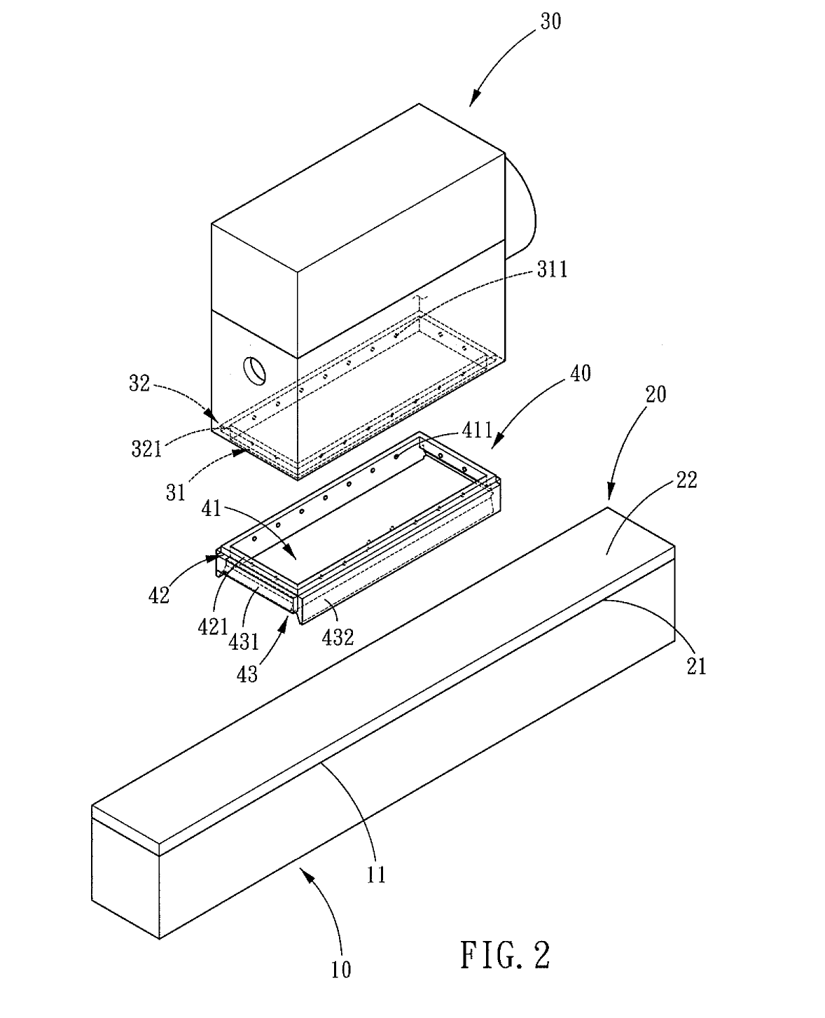

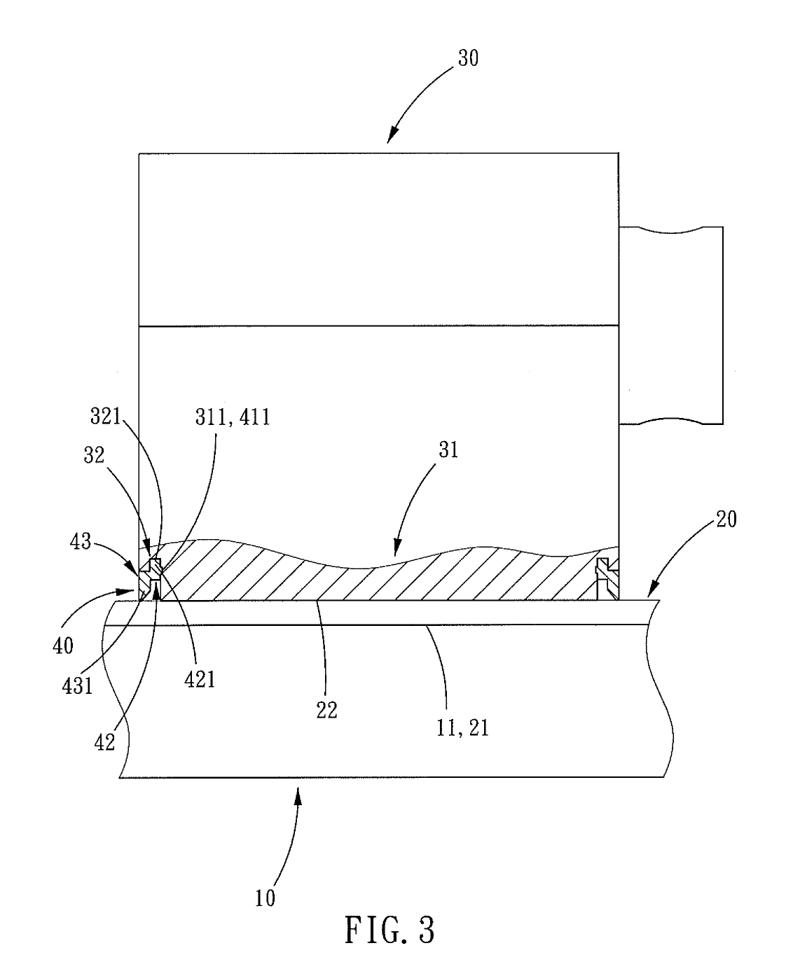

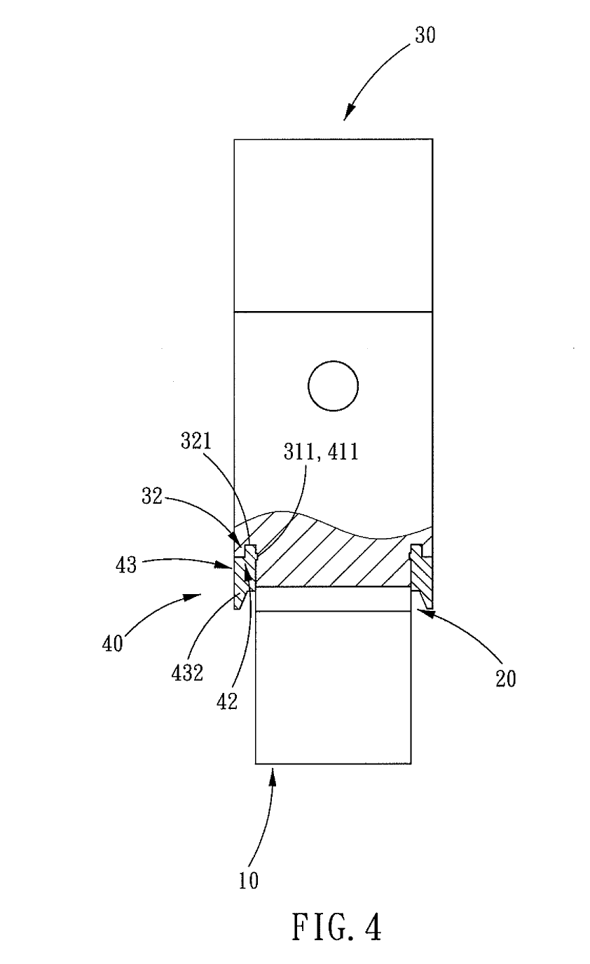

Referring to FIGS. 2-4, a magnetic induction protecting structure in accordance with the present invention comprises a platform 10, an induction ruler 20, an induction head 30 and a protection assembly 40.

The platform 10 is rectangular strip-shaped, at a top side of the platform 10 is formed a flat positioning portion 11.

The induction ruler 20 is rectangular sheet-shaped, at a bottom side and a top side of the induction ruler 20 is formed a flat positioning portion 21 and a flat magnetic portion 22 respectively, and the induction ruler 20 is positioned to the platform 10.

The above-mentioned is the description of the conventional structure, the induction head 30 and the protection assembly 40 of the present invention are improved, and the protection assembly 40 is assembled between the induction head 30 and the induction ruler 20.

The induction head 30 is rectangular block-shaped, at an end of a bottom of the induction head 30 are orderly formed a magnetic induction portion 31 and a first jointing portion 32 from inner to outside.

The magnetic induction portion 31 is magnetically inducted by the magnetic portion 22 of the induction ruler 20, between the magnetic induction portion 31 and the magnetic portion 22 is formed an induction distance A, and in an outer periphery of the magnetic induction portion 31 is annularly and equidistantly defined a plurality of positioning holes 311.

The first jointing portion 32 is located at the periphery of the magnetic induction portion 31 and is formed with an annular locking groove 321.

The protection assembly 40 is frame-shaped, in a center of the protection assembly 40 is defined a through hole 41, and the shape of the through hole 41 is the same as that of the magnetic induction portion 31 of the induction head 30. On an inner periphery of the through hole 41 is annularly and equidistantly defined a plurality of positioning ribs 411, and the shape of the positioning ribs 411 is the same as that of the positioning holes 311 of the magnetic induction portion 31.

One side of the protection assembly 40 is formed with a second jointing portion 42 around the through hole 41, and the other side of the protection assembly 40 is formed with an anti-dust portion 43 around the through hole 41.

The second jointing portion 42 is formed with an annular protruded rib 421 to be inserted into the locking groove 321 of the first jointing portion 32, and the positioning ribs 411 of the protection assembly 40 are inserted into the positioning holes 311 of the magnetic induction portion 31.

The anti-dust portion 43 has two scraping portions 431 and two insulating portions 432.

The scraping portions 431 are sheet-shaped and are oppositely formed at both ends of the anti-dust portion 43, and the scraping portions 431 extends to the magnetic portion 22 of the induction ruler 20 respectively.

The insulating portions 432 are sheet-shaped, and the length of the insulating portion 432 is longer than that of the scraping portion 431. The insulating portions 432 are oppositely formed at both sides of the anti-dust portion 43 and are located adjacent to the scraping portions 431, and the insulating portions 432 are protruded out of the sides of the induction ruler 20, such that the scraping portions 431 and the insulating portions 432 of the anti-dust portion 43 of the protection assembly 40 will cover the induction distance A between the induction head 30 and the induction ruler 20 completely.

For a better understanding of the present invention, its operations and functions, reference should be made to FIGS. 2-4:

A. the scraping portions 431 and the insulating portions 432 of the anti-dust portion 43 of the protection assembly 40 can cover the induction distance A between the induction head 30 and the induction ruler 20 completely, enabling the scraping portions 431 of the anti-dust portion 43 to scrape the chips and dust off the induction ruler 20 during displacement of the induction head 30. In addition, the insulating portions 432 of the anti-dust portion 43 are provided for preventing the chips and dust from being fallen into or accumulated in the induction distance A.

The above-mentioned is the description of the induction ruler 20, the induction head 30 and the protection assembly 40, the protection assembly 40 covers the induction distance A between the induction head 30 and the induction ruler 20 completely for scraping off the chips and dust accumulated on the induction ruler 20 and to prevent the chips and dust from being fallen into or accumulated in the induction distance A, so as to ensure the quality of the magnetic induction signals between the induction head 30 and the induction ruler 20, and to prolong the life of the induction head 30 and the induction ruler 20.

B. the magnetic induction portion 31 of the induction head 30 is assembled in the through hole 41 of the protection assembly 40, the protruded rib 421 of the second jointing portion 42 of the protection assembly 40 is inserted into the locking groove 321 of the first jointing portion 32 of the induction head 30, and the positioning ribs 411 of the through hole 41 of the protection assembly 40 are inserted into the positioning holes 311 of the magnetic induction portion 31 of the induction head 30.

The above-mentioned is the description of the assembly of the induction head 30 and the protection assembly 40, and the induction head 30 is assembled to the protection assembly 40 directly without cooperating with any other components, so as to save assembly time and to reduce the cost.

To summarize, a magnetic induction protecting structure of the present invention comprises a platform, an induction ruler, an induction head and a protection assembly. The protection assembly covers an induction distance between the induction head and the induction ruler completely for scraping off the chips and dust on the induction ruler and to prevent the chips and dust from being fallen into or accumulated in the induction distance, so as to ensure the quality of the magnetic induction signals between the induction head and the induction ruler, and to prolong the life of the induction head and the induction ruler.

While we have shown and described various embodiments in accordance with the present invention, it should be clear to those skilled in the art that further embodiments may be made without departing from the scope of the present invention.

What is claimed is:

1. A magnetic induction protecting structure, comprising:
an induction ruler;
an induction head, between the induction head and the induction ruler being formed an induction distance;
a protection assembly, one side of the protection assembly being assembled to the induction head, and the other side of the protection assembly extends to the induction ruler, enabling the protection assembly to cover the induction distance between the induction head and the induction ruler.

2. The magnetic induction protecting structure as claimed in claim 1, wherein:
one side of the induction ruler is formed with a magnetic portion;
the induction head is formed with a magnetic induction portion and a first jointing portion at one end thereof, between the magnetic induction portion and the magnetic portion is formed an induction distance;
one side of the protection assembly is formed with a second jointing portion, the other side of the protection assembly is formed with an anti-dust portion, the second jointing portion of the protection assembly is assembled correspondingly to the first jointing portion of the induction head, and the anti-dust portion of the protection assembly extends to the magnetic portion of the induction ruler, enabling the protection assembly to cover the induction distance between the induction head and the induction ruler.

3. The magnetic induction protecting structure as claimed in claim 2, wherein the magnetic induction portion and the first jointing portion are formed at one end of the induction head from inner to outside;
in an outer periphery of the magnetic induction portion is annularly and equidistantly defined a plurality of positioning holes;
the first jointing portion is located at the periphery of the magnetic induction portion and is formed with an annular locking groove.

4. The magnetic induction protecting structure as claimed in claim 3, wherein in a center of the protection assembly is defined a through hole, the shape of the through hole is the same as that of the magnetic induction portion of the induction head, on an inner periphery of the through hole is annularly and equidistantly defined a plurality of positioning ribs, and the shape of the positioning ribs is the same as that of the positioning holes of the magnetic induction portion.

5. The magnetic induction protecting structure as claimed in claim 4, wherein one side of the protection assembly is formed with a second jointing portion around the through hole, the other side of the protection assembly is formed with an anti-dust portion around the through hole;
the second jointing portion is formed with a protruded rib to be inserted into the locking groove of the first jointing portion, the positioning ribs of the protection assembly are inserted into the positioning holes of the magnetic induction portion;
the anti-dust portion has two scraping portions and two insulating portions; the scraping portions are oppositely formed at both ends of the anti-dust portion, the scraping portions extends to the magnetic portion of the induction ruler respectively; the length of the insulating portion is longer than that of the scraping portion, the insulating portions are oppositely formed at both sides of the anti-dust portion and are located adjacent to the scraping portions, and the insulating portions are protruded out of the sides of the induction ruler.

6. The magnetic induction protecting structure as claimed in claim 5, wherein:
the protection assembly is frame-shaped;
the scraping portions of the anti-dust portion are sheet-shaped; and
the insulating portions of the anti-dust portion are sheet-shaped.
